(19) United States
(12) Patent Application Publication
(10) Pub. No.: US 2023/0178527 A1
(43) Pub. Date: Jun. 8, 2023

(54) DEVICE ARRAY SUBSTRATE

(71) Applicant: AUO Corporation, Hsin-Chu (TW)

(72) Inventors: Kent-Yi LEE, Hsin-Chu (TW); Kung-Cheng LIN, Hsin-Chu (TW)

(21) Appl. No.: 18/072,788

(22) Filed: Dec. 1, 2022

(30) Foreign Application Priority Data
Dec. 3, 2021 (TW) 110145363

(51) Int. Cl. H01L 25/075; H01L 33/62; H01L 33/20

(52) U.S. Cl. CPC H01L 25/0753; H01L 33/62; H01L 33/20

(57) ABSTRACT

A device array substrate includes a flexible substrate, multiple trace units and multiple sub-pixel units. The flexible substrate includes an island portion and multiple connecting portions. The island portion has a rectangular-shaped center structure and multiple peripheral structures connected to side surfaces of the center structure. The connecting portions are connected to the center structure through the peripheral structures. Each connecting portion has at least one edge being arc-shaped. The trace units are disposed on the connecting portions. The sub-pixel units are disposed on the island portion and electrically connected to the trace units. The sub-pixel units include a first sub-pixel unit on the center structure and closest to one side surface of the center structure. A maximum distance between the first sub-pixel unit and an edge of the island portion along a direction perpendicular to the side surface of the center structure is 5 μm to 45 μm.

### CROSS-REFERENCE TO RELATED PATENT APPLICATION

This non-provisional application claims priority to and the benefit of, pursuant to 35 U.S.C. § 119(a), patent application Serial No. 110145363 filed in Taiwan on Dec. 3, 2021. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to a device array substrate.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A flexible display may deform in any direction and has stretchability and resilience, and thus may be flexibly applicable to a wearable display or a medical display. The substrate of the flexible display has an island portion region, and the island portion region may be implanted with essential components such as light emitting diodes (LEDs) or transistors. However, when the implanting direction of the LEDs cannot be consistent with the direction of the island portion region, some of the LEDs may be very close to the edge of the island portion region, thus affecting the yield thereof. Further, in the subsequent overcoat (OC) manufacturing process, it is possible that the LEDs may not fit into the island portion region.

### SUMMARY

The present disclosure provides a device array substrate, which increases the convenience of implanting the display components while maintaining the existing deformation amount.

In one aspect of the present disclosure, a device array substrate includes a flexible substrate, a plurality of trace units and a plurality of sub-pixel units. The flexible substrate includes an island portion and a plurality of connecting portions. The island portion has a center structure and a plurality of peripheral structures. The peripheral structures are connected to side surfaces of the center structure, and the center structure is rectangular-shaped. The connecting portions are respectively connected to the center structure through each of the peripheral structures, and each of the connecting portions has at least one edge being arc-shaped. The trace units are disposed on each of the connecting portions. The sub-pixel units are disposed on the island portion and are electrically connected to one of the trace units. The sub-pixel units include a first sub-pixel unit, located on the center structure and closest to one of the side surfaces of the center structure. A maximum distance between the first sub-pixel unit and an edge of the island portion along a direction perpendicular to the one of the side surfaces of the center structure is 5 μm to 45 μm.

In another aspect of the present disclosure, a device array substrate includes a flexible substrate, a plurality of trace units and a plurality of sub-pixel units. The flexible substrate includes an island portion and a plurality of connecting portions. The island portion has a center structure and a plurality of peripheral structures. The peripheral structures are connected to side surfaces of the center structure, and the center structure is rectangular-shaped. A total area of the peripheral structures is less than or equal to one half of an area of the center structure. The connecting portions are respectively connected to the center structure through each of the peripheral structures, and each of the connecting portions has at least one edge being arc-shaped. The trace units are disposed on each of the connecting portions. The sub-pixel units are disposed on the island portion and are electrically connected to one of the trace units.

Based on the foregoing, in the device array substrate according to certain embodiments of the present disclosure, the sub-pixel units include a first sub-pixel unit, the first sub-pixel unit is located on the center structure and closest to one of the side surfaces of the center structure, and a maximum distance between the first sub-pixel unit and an edge of the island portion along a direction perpendicular to the one of the side surfaces of the center structure is 5 μm to 45 μm. Thus, the convenience of implanting display components may be increased, and the existing deformation amount may be maintained.

These and other aspects of the present disclosure will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a top schematic view of a device array substrate according to an embodiment of the present disclosure.

FIG. 2 is a sectional schematic view of FIG. 1 along a line A-A′.

FIG. 3 is a top schematic view of a circumscribed circle of a center structure of an island portion and the sub-pixel units according to an embodiment of the present disclosure.

FIG. 4 is a top schematic view of a circumscribed circle of a center structure of an island portion and the sub-pixel units according to another embodiment of the present disclosure.

FIG. 5 is a top schematic view of a circumscribed circle of a center structure of an island portion and the sub-pixel units according to yet another embodiment of the present disclosure.

FIG. 6 is a top schematic view of a circumscribed circle of a center structure of an island portion and the sub-pixel units according to a further embodiment of the present disclosure.

### DETAILED DESCRIPTION

The detailed features and advantages of the present disclosure are described below in great detail through the following embodiments, and the content of the detailed description is sufficient for persons skilled in the art to understand the technical content of the present invention and to implement the present invention there accordingly. Based upon the content of the specification, the claims, and the drawings, persons skilled in the art can easily understand the relevant objectives and advantages of the present invention. The following embodiments further describe the viewpoints of the present invention, but are not intended to limit the scope of the present invention in any way.

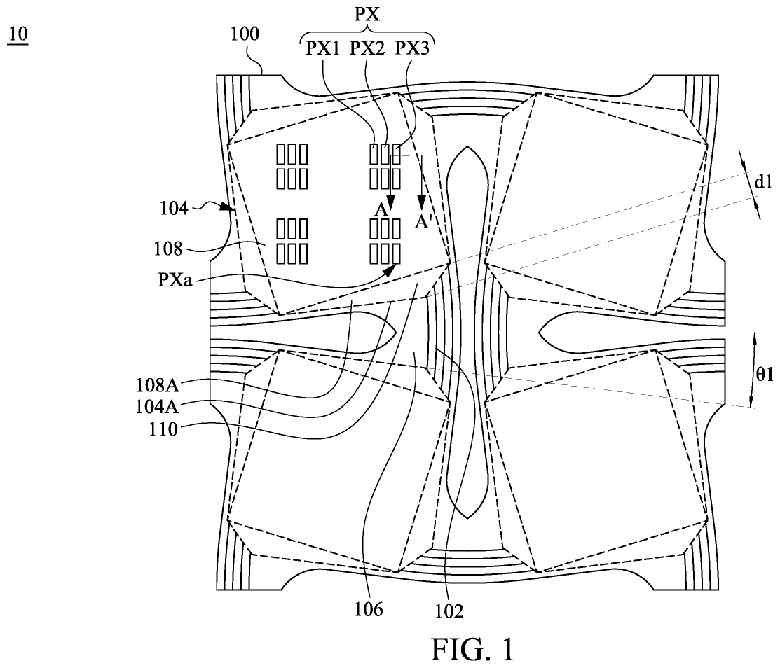

FIG. 1 is a top schematic view of a device array substrate 10 according to an embodiment of the present disclosure. Referring to FIG. 1, the device array substrate 10 includes a flexible substrate 100, a plurality of trace units 102 and a plurality of sub-pixel units PX. The material of the flexible substrate 100 may be polyimide (PI), polycarbonate (PC), polyester, cyclic olefin copolymer (COC), metallocene-based cyclic olefin copolymer (mCOC) or other suitable materials, but the present disclosure is not limited thereto.

The flexible substrate 100 includes an island portion 104 and a plurality of connecting portions 106. The island portion 104 has a center structure 108 and a plurality of peripheral structures 110. The peripheral structures 110 are connected to side surfaces 108A of the center structure 108, and the center structure 108 is rectangular-shaped. The connecting portions 106 are respectively connected to the center structure 108 through each of the peripheral structures 110, and each of the connecting portions 106 has at least one edge being arc-shaped. For example, one edge of each connecting portion 106 may be arc-shaped.

Each sub-pixel unit PX includes a sub-pixel PX1, a sub-pixel PX2 and a sub-pixel PX3. The sub-pixels PX1, PX2, PX3 may respectively present different colors. For example, the display component 112 in the sub-pixel PX1 is a red LED, the display component 112 in the sub-pixel PX2 is a green LED, and the display component 112 in the sub-pixel PX3 is a blue LED, but the present disclosure is not limited thereto. The trace units 102 are disposed on each of the connecting portions 106. The sub-pixel units PX are disposed on the island portion 104 and are electrically connected to one of the trace units 102.

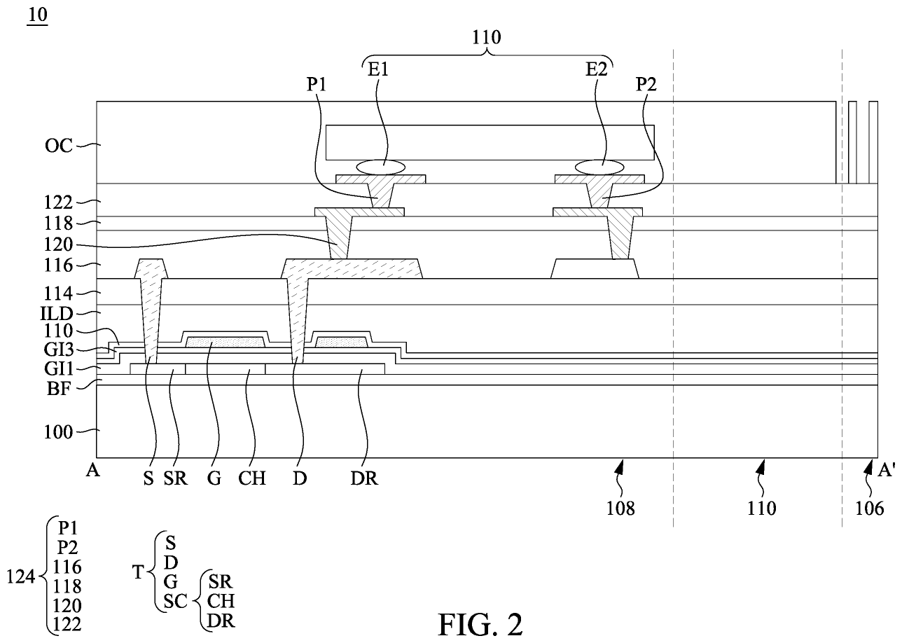

FIG. 2 is a sectional schematic view of FIG. 1 along a line A-A′. Referring to both FIG. 1 and FIG. 2, in the present embodiment, the flexible substrate 100 has a buffer layer BF, a semiconductor layer SC, a gate electrode insulating layer GI1, a gate electrode insulating layer GI3, a gate electrode G, an overcoat layer 111, an inter-layer insulating layer ILD, a first insulating layer 114, a source electrode S and a drain electrode D. The semiconductor layer SC, the gate electrode G, the source electrode S and the drain electrode D collectively form an active component T. Materials of the buffer layer BF, the gate electrode insulating layer GI1, the gate electrode insulating layer GI3, the overcoat layer 111, the inter-layer insulating layer ILD and the first insulating layer 114 may include transparent insulating materials, such as silicon oxide, silicon nitride, silicon oxynitride, etc., but the present disclosure is not limited thereto. The materials of the semiconductor layer SC may include silicon-based semiconductor materials (such as poly-silicon, amorphous silicon, etc.), oxide semiconductor materials, and organic semiconductor materials, and the materials of the gate electrode G, the source electrode S and the drain electrode D may include metals with good electrical conductivity, such as aluminum, molybdenum, titanium, copper, etc.

The region of the semiconductor layer SC overlapping with the gate electrode G is viewed as a channel region CH of the active component T. The gate electrode insulating layers GI1, GI3 are located between the gate electrode G and the semiconductor layer SC, and the inter-layer insulating layer ILD and the first insulating layer 114 are disposed between the source electrode S and the gate electrode G and between the drain electrode D and the gate electrode G. The semiconductor layer SC includes a source region SR, a drain region DR and the channel region CH. The source electrode S and the drain electrode D run through the inter-layer insulating layer ILD, the overcoat layer 111 and the gate electrode insulating layers GI1, GI3 to be respectively electrically connected to the source region SR and the drain region DR of the semiconductor layer SC.

In addition, the active component T in the present embodiment belongs to a top gate electrode type thin film transistor. However, in other embodiments, the active component T may be a bottom gate electrode type thin film transistor, a duel gate electrode type thin film transistor, or other types of thin film transistors.

The device array substrate 10 further includes a circuit layer 124. The circuit layer 124 includes at least one insulating layer and at least one wire layer, and the wire layer of the circuit layer 124 electrically connects the active component T to a first pad P1 and a second pad P2. In the present embodiment, the circuit layer 124 includes a second insulating layer 116, a third insulating layer 118, a first wire layer 120, a fourth insulating layer 122, the first pad P1 and the second pad P2. The second insulating layer 116 and the third insulating layer 118 are located between the active component T and the first wire layer 120. The fourth insulating layer 122 is located between the first wire layer 120 and the first pad P1, the second pad P2. The first wire layer 120 electrically connects the drain electrode D of the active component T to the first pad P1.

In the present embodiment, the display component 112 includes a first electrode E1 and a second electrode E2, disposed at a side of the display component 112 facing the circuit layer 124. For example, the display component 112 in the present embodiment is a horizontal micro LED, the first electrode E1 is an anode, and the second electrode E2 is a cathode, but the present disclosure is not limited thereto. In the present embodiment, the first electrode E1 is electrically coupled to the first pad P1, and the second electrode E2 of the display component 112 is electrically coupled to the second pad P2. In the present embodiment, the materials of the first electrode E1 and the second electrode E2 may include alloys, metal nitride, metal oxide, metal oxynitride or other suitable materials, a stack layer of metal materials and other conductive materials, or other materials with low resistances.

The materials of the second insulating layer 116, the third insulating layer 118 and the fourth insulating layer 122 may include insulating materials, such as silicon oxide, silicon nitride, silicon oxynitride, etc., but the present disclosure is not limited thereto. In addition, the second insulating layer 116, the third insulating layer 118 and the fourth insulating layer 122 may respectively have single-layer structures or multi-layer structures, and the multi-layer structures may be stack layers of any two or more layers of the insulating materials as disclosed above, which may be combined and changed based on the need.

The materials of the first wire layer 120, the first pad P1 and the second pad P2 may be metals with good electrical conductivity, such as aluminum, aluminum, molybdenum, titanium, copper, etc. For example, the first wire layer 120, the first pad P1 and the second pad P2 may be multi-layer structures, and include a titanium layer, an aluminum layer and a titanium layer sequentially stacked, but the present disclosure is not limited thereto.

The sub-pixel units PX includes a first sub-pixel unit PXa. The first sub-pixel unit PXa is located on the center structure 108 and closest to one of the side surfaces 108A of the center structure 108. Since the island portion 104 has the center structure 108 and a plurality of peripheral structures 110, the peripheral structures 110 are connected to the side surfaces 108A of the center structure 108, and the center structure 108 is rectangular-shaped, a distance between the first sub-pixel unit PXa and an edge 104A of the island portion 104 is increased. For example, a maximum distance d1 between the first sub-pixel unit PXa and the edge 104A of the island portion 104 along a direction perpendicular to the one side surface 108A of the center structure 108 is 5 μm to 45 μm, and is preferably 5 μm to 25 μm. Thus, the convenience of implanting the display component 112 may be increased on the condition of not changing the pre-rotation angle θ1 of the flexible substrate 100, and a total existing deformation amount of the device array substrate 10 may be maintained. For example, the pre-rotation angle θ1 of the flexible substrate 100 may be maintained between 12° and 13°.

In one embodiment, the overcoat OC is located on the display component 112. Since the island portion 104 has the center structure 108 and a plurality of peripheral structures 110, the peripheral structures 110 are connected to the side surfaces 108A of the center structure 108, and the center structure 108 is rectangular-shaped, when the display component 112 is implanted, it will not be blocked by the overcoat OC.

In one embodiment, a total area of the peripheral structures 110 is less than or equal to one half of an area of the center structure 108. Thus, the convenience of implanting the display component 112 may be increased on the condition of not changing the pre-rotation angle θ1 of the flexible substrate 100, and a total existing deformation amount of the device array substrate 10 may be maintained. For example, the pre-rotation angle θ1 of the flexible substrate 100 may be maintained between 12° and 13°.

In one embodiment, the center structure 108 and the peripheral structures 110 of the island portion 104 are integrally formed. In one embodiment, a thickness of each of the peripheral structures 110 is less than a thickness of the center structure 108.

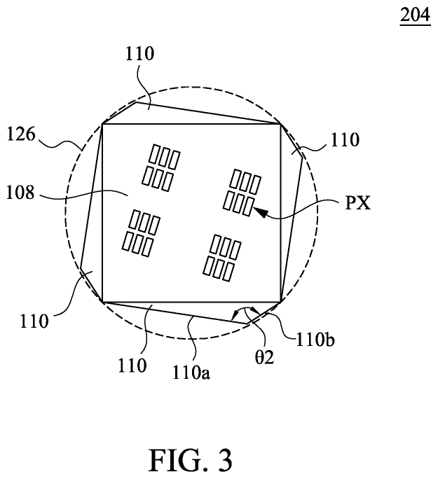

FIG. 3 to FIG. 6 are top schematic views of a circumscribed circle 126 of a center structure 108 of an island portion 204, 304, 404, 504 and the sub-pixel units PX according to certain embodiments of the present disclosure. Referring firstly to FIG. 3, the overall size of the center structure 108 and the peripheral structure 110 does not exceed the circumscribed circle 126 of the center structure 108. In one embodiment, each peripheral structure 110 is triangular-shaped, such as an obtuse triangle. Each peripheral structure 110 has a first side 110a and a second side 110b connected to each other, and an included angle θ2 between the first side 110a and the second side 110b is between 135° and 180°.

In other embodiments, the peripheral structures 110 may be polygonal-shaped. In the present embodiment, a length of the first side 110a is different from a length of the second side 110b. For example, the length of the first side 110a is greater than the length of the second side 110b.

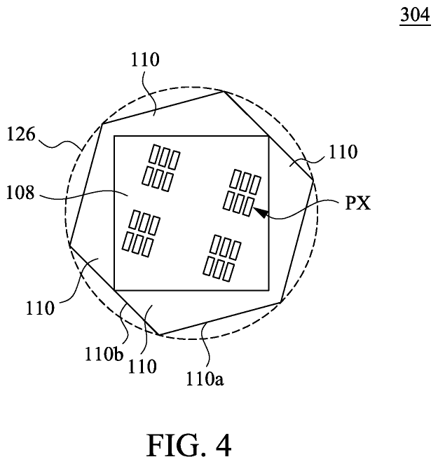

In one embodiment, the peripheral structures 110 of the island portion 204 may be formed by straight lines. For example, the island portion 204 is octagonal-shaped (see FIG. 3). In other embodiments, the island portion 304 is hexagonal-shaped (see FIG. 4).

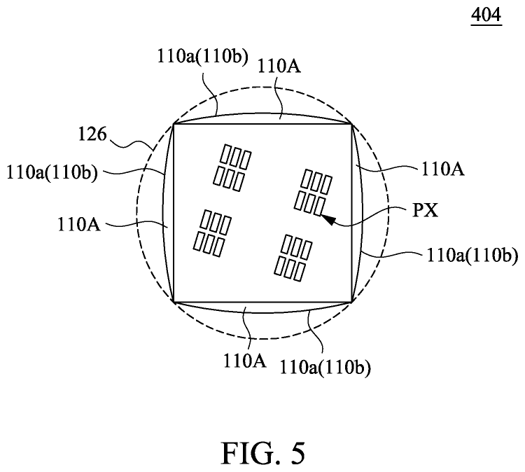

In certain embodiments, the peripheral structures 110A may have arc-shaped edges. For example, in one embodiment, the first side 110a and the second side 110b of each of the peripheral structures 110A collectively form an arc-shaped edge (see FIG. 5).

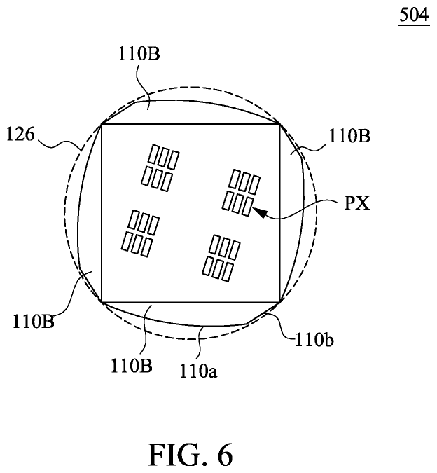

In other embodiments, the first side 110a of each of the peripheral structures 110B is arc-shaped, and the second side 110b of each of the peripheral structures 110B is straight (see FIG. 6).

In sum, the sub-pixel units include a first sub-pixel unit, and the first sub-pixel unit is located on the center structure and closest to one of the side surfaces of the center structure. Since the island has a center structure and a plurality of peripheral structures, the peripheral structures are connected to the side surfaces of the center structure, and the center structure is rectangular-shaped, a distance between the first sub-pixel unit and an edge of the island portion is increased. For example, a maximum distance between the first sub-pixel unit and the edge of the island portion along a direction perpendicular to the one side surface of the center structure may be 5 μm to 25 μm. Thus, the convenience of implanting the display component may be increased on the condition of not changing the pre-rotation angle of the flexible substrate, and the existing deformation amount of the device array substrate may be maintained.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A device array substrate, comprising:
a flexible substrate, comprising:
an island portion, having a center structure and a plurality of peripheral structures, wherein the peripheral structures are connected to side surfaces of the center structure, and the center structure is rectangular-shaped; and
a plurality of connecting portions, respectively connected to the center structure through each of the peripheral structures, wherein each of the connecting portions has at least one edge being arc-shaped;
a plurality of trace units, disposed on each of the connecting portions; and
a plurality of sub-pixel units, disposed on the island portion and electrically connected to one of the trace units, wherein the sub-pixel units comprise:
a first sub-pixel unit, located on the center structure and closest to one of the side surfaces of the center structure, wherein a maximum distance between the first sub-pixel unit and an edge of the island portion along a direction perpendicular to the one of the side surfaces of the center structure is 5 μm to 45 μm.

2. The device array substrate according to claim 1, wherein the center structure and the peripheral structures are integrally formed.

3. The device array substrate according to claim 1, wherein a thickness of each of the peripheral structures is less than a thickness of the center structure, and the maximum distance between the first sub-pixel unit and an edge of the island portion along a direction perpendicular to the one of the side surfaces of the center structure is 5 μm to 45 μm.

4. The device array substrate according to claim 1, wherein each of the peripheral structures has a first side and a second side connected to each other, and an included angle between the first side and the second side is between 135° and 180°.

5. The device array substrate according to claim 4, wherein the first side and the second side of each of the peripheral structures collectively form an arc-shaped edge.

6. The device array substrate according to claim 4, wherein the first side of each of the peripheral structures is arc-shaped, and the second side of each of the peripheral structures is straight.

7. The device array substrate according to claim 4, wherein a length of the first side is different from a length of the second side.

8. A device array substrate, comprising:
a flexible substrate, comprising:
an island portion, having a center structure and a plurality of peripheral structures, wherein the peripheral structures are connected to side surfaces of the center structure, the center structure is rectangular-shaped, and a total area of the peripheral structures is less than or equal to one half of an area of the center structure; and
a plurality of connecting portions, respectively connected to the center structure through each of the peripheral structures, wherein each of the connecting portions has at least one edge being arc-shaped;
a plurality of trace units, disposed on each of the connecting portions; and
a plurality of sub-pixel units, disposed on the island portion and electrically connected to one of the trace units.

9. The device array substrate according to claim 8, wherein the island portion is octagonal-shaped.

10. The device array substrate according to claim 8, wherein the island portion is hexagonal-shaped.
